(19) United States
(12) Patent Application Publication
(10) Pub. No.: US 2026/0239668 A1
(43) Pub. Date: Aug. 13, 2026

(54) SEMICONDUCTOR DIE WITH A VERTICAL TRANSISTOR DEVICE

(71) Applicant: Infineon Technologies Austria AG, Villach (AT)

(72) Inventor: Alessandro Ferrara, Villach (AT)

(21) Appl. No.: 19/459,672

(22) Filed: Jan. 26, 2026

(30) Foreign Application Priority Data
Feb. 10, 2025 (DE) 102025000490.7

(51) Int. Cl. H10D 30/66; H10D 30/01; H10D 64/00

(52) U.S. Cl. CPC H10D 30/669; H10D 30/0291; H10D 30/668; H10D 64/117

(57) ABSTRACT

The application relates to a semiconductor die with a semiconductor body. The semiconductor die includes a vertical transistor device and a current sense transistor device. The current sense transistor device is configured to sense an electrical current through the vertical transistor device. An additional resistance is integrated in the semiconductor die and arranged on a drain side of the current sense transistor device.

### TECHNICAL FIELD

The present disclosure relates to a semiconductor die with a semiconductor body, comprising a vertical transistor device.

### BACKGROUND

A vertical transistor device may have a source region at a first side and a drain region at a second side of the semiconductor body. The semiconductor die may additionally comprise a current sense transistor device, wherein the vertical transistor device and the current sense transistor device may be connected as a current mirror. In this circuit, the current through one device is copied to the other device, e.g. a load current I_{L} from the vertical transistor device to a sense current I_{S} in the current sense transistor device. Therein, the sense current may be proportional to the load current, wherein a proportionality factor can be given by a ratio between a size of the vertical transistor device and a size of the current sense transistor device. This size ratio may be equivalent to a ratio between the respective number of transistor cells and/or a ratio between the transistor areas.

### SUMMARY

Examples of the present application are directed at an advantageous semiconductor die.

In an embodiment, a semiconductor die comprises a vertical transistor device, which has a source region and a drain region at opposite sides of a semiconductor body. The semiconductor die further comprises a current sense transistor device, which has a sense source region and a sense drain region in the semiconductor body. The semiconductor die further comprises an additional resistance, which is integrated into the semiconductor die and is arranged on a drain side of the current sense transistor device.

The additional resistance may keep the vertical and the current sense transistor matched, e.g. improve a matching between the proportionality factor and the size ratio. The current ratio, i.e. I_{L}/I_{S}, is also referred to as a k_{ILIS} factor, which in an ideal case describes a predefined proportionality between the load current I_{L} and the sense current I_{S}. However, the proportionality factor may vary, e.g. due to a current spreading in the current sense transistor device. The additional resistance may compensate for this current spreading in the sense transistor, which can for instance occur in its drift region and/or substrate.

The additional resistance on the drain side may allow for a stabilized compensation, for instance across different operating conditions. For comparison, a compensation implemented on the source side in some cases might have a stronger dependence from, e.g., the temperature value, the gate voltage or a current level (the latter with a minor impact). Generally, a deviation of the current ratio from the size ratio may increase as the size of the current sense transistor decreases relative to the size of the vertical transistor device. Consequently, the compensation achieved with the additional resistance may allow for an increased accuracy and/or for a smaller layout or size of the current sense transistor device, e.g. to reduce losses associated with the current measurement.

Further embodiments and features are provided in the claims and throughout this disclosure. Therein, the individual features shall be disclosed independently of a specific claim category, the disclosure relates to apparatus and device aspects but also to method and use aspects. If for instance a die manufactured in a specific way is described, this is also a disclosure of a respective manufacturing process, and vice versa. In general words, embodiments of the present application aim at providing a current sense transistor device with an additional resistance on its drain side. The additional resistance may increase a resistance of the current sense transistor device by, for instance, at least 5%. Possible upper limits being for instance at most 200%, 100%, 50% or 20%.

The additional resistance is integrated in the semiconductor die, e.g. into the semiconductor body and/or into a layer or layer stack disposed on the semiconductor body. Referring to an outer circumference of the semiconductor die, the additional resistance may be arranged inside thereof.

In a device structure of the current sense transistor device, the "drain side" may begin at a transition from a drift region of the current sense transistor device into the sense drain region, or at a transition from the body region of the current sense transistor device into the drift region of the current sense device. For example, the drain side may begin at an end (e.g., bottom end) of the body region of the current sense transistor device. The end (e.g., bottom end) of the body region may lie adjacent to the sense drain region or have another region in between, e.g. a drift region of the current sense transistor device (“sense drift region”, see below).

In some embodiments, the "drain side" may be the point from which the drain region of the current sense transistor device extends in the semiconductor body (e.g. vertically downwards in case of a vertical current sense transistor device). In other words, the "drain side" may be the upper side of the drain region and/or may be arranged at a transition from a body region (of the current sense transistor device) or drift region (of the current sense transistor device) into the drain region (of the current sense transistor device).

The current sense transistor device is "configured for sensing" an electrical current through the vertical transistor device, e.g. is connected or is to be connected (e.g. in the package) as a current mirror. The gate electrode of the vertical transistor device and the gate electrode of the current sense transistor device may be electrically connected to each other in the die (in general, they might be connected externally), e.g. in the semiconductor body and/or in a layer or layer stack on the semiconductor body. The drain region of the vertical transistor device and the sense drain region may be electrically connected to each other via the additional resistance in the semiconductor die, e.g. in the semiconductor body and/or in a layer or layer stack thereon.

The source region and the drain region of the vertical transistor device are disposed at vertically opposite sides of the semiconductor body, wherein the "first side" can also be referred to as a frontside and the "second side" as a backside. In a body region of the vertical transistor device, a channel can be formed by applying a voltage to the gate electrode of the vertical transistor device. Even though the transistor device as a whole is considered "vertical" due to its vertically opposite source and drain region, a lateral channel is conceivable in general, e. g. in case of a gate region disposed on top of the body region (and a source region laterally aside the latter). This shall also be included in the term “vertical transistor device”. In particular embodiments, however, the gate region is disposed laterally aside the body region and the channel extends vertically aside a trench, see in detail below.

"Vertical" or "vertically" refer to the vertical direction which lies for instance perpendicular to a surface of the die, e. g. the surface of a substrate or an epitaxial layer formed on the substrate. "Lateral" or "laterally" refer to the lateral directions perpendicular to the vertical direction, in which for instance the die area is taken. On the first side of the semiconductor body, an insulating layer can be disposed, on which one or more metallization layers can be formed.

In detail, the additional resistance can be arranged at various locations of the semiconductor die/body and be implemented in different ways, which is discussed in detail below.

In an embodiment, at least a portion of the additional resistance is integrated in the semiconductor body below the drain side of the current sense transistor device. The semiconductor body may comprise a semiconductor substrate and, optionally, one or more epitaxial semiconductor layers formed on the semiconductor substrate. Referring to the "drain side" as discussed above, at least a portion of the resistance may be arranged in the drain region, e.g. in the sense drain region. In other words, at least a portion of the additional resistance may be formed in the semiconductor substrate.

In an embodiment, the current sense transistor device comprises a sense drift region. In some examples, the sense drift region may be formed in an epitaxial layer on the semiconductor substrate, e.g., the same epitaxial layer comprising for instance a drift region of the vertical transistor device. An increased resistance in the sense drift region may be combined with an increased resistance in the sense drain region or semiconductor substrate. In other words, a portion of the additional resistance may respectively be added in each of the drift region and the drain region of the current sense transistor device.

In an embodiment, at least a portion of the additional resistance is realized by a decreased conductivity in the semiconductor body by a removal of current flow lines. As seen for instance in a vertical cross-section through the current sense transistor device, a current flow field on the drain side may be considered, i.e. a current flow field in the sense drift and/or sense drain region. As discussed above, a deviation of the proportionality factor or mismatch of the devices may result from a current spreading, e.g. a divergence of the current flow lines from the channel of the sense device towards the second side of the semiconductor body. By removing current flow lines from the current flow field, the conductivity may be decreased, and thereby additional resistance is added. Various options for a removal of current flow lines are discussed below, the conductivity being for instance decreased by "cutting out" central and/or peripheral current flow lines.

In an embodiment, the semiconductor die comprises a backside metallization which is arranged on the second side of the semiconductor body. Towards the second side of the semiconductor body, the backside metallization has a contact area where an electrical contact is formed between the semiconductor body and the metallization.

In an embodiment, the contact area has an interruption below the current sense transistor device. Where the interruption is arranged, current flow lines may be removed or "cut out", see FIG. 2 for illustration. In other words, the interruption of the contact area may "cut out" a direct vertical path down to the second side of the semiconductor body. Viewed from a different perspective, to compensate for a possible mismatch resulting from a current spreading, the current spreading may even be increased (to extend the current path and resistance, thus).

The interruption, as viewed in a vertical cross-section, can for instance extend over at least 10% of a lateral width of the current sense transistor device. Further lower limits may be at least 50%, 100% or 200%, the interruption may extend over and even beyond the entire lateral width of the current sense transistor device. Considering a current sense transistor device having a gate trench or trenches, the sectional plane of this cross-sectional view may lie perpendicular to a length direction of the gate trench(es). The lateral width may be taken over the active cells of the current sense transistor device.

In an embodiment, the semiconductor die comprises an insulating element, which is arranged on the second side of the semiconductor body where the contact area has the interruption. The insulating element may be formed in a single layer or layer stack, which is deposited onto the second side and structured to form the insulating element. As an alternative or in addition to the insulating element, the backside metallization may be structured, i.e. be interrupted locally to form the interrupted contact area.

In an embodiment, however, the backside metallization extends uninterrupted across the insulating element, and the contact area is interrupted by the insulating element. In other words, the insulating element may be formed in a structured insulating layer or layer stack, across which the backside metallization may extend uninterrupted, e.g. to cover the entire backside. In the area of the interruption, the insulating element may extend continuously or be structured. In other words, the interruption of the contact area may be a continuous area or may be structured as well.

In an embodiment, the semiconductor die comprises a deep trench isolation. The deep trench isolation may extend from the first side of the semiconductor body into the semiconductor body, e.g. reach from the first side to the second side of the semiconductor body. An isolation trench of the deep trench isolation may be provided with an insulating filler or liner, for instance an insulating liner in combination with a filler that may be non-conductive or conductive (e.g. a silicon oxide liner and a polysilicon filler).

The deep trench isolation may be arranged laterally between the vertical transistor device and the current sense transistor device. As viewed in a vertical cross-section, the sectional plane lying for instance perpendicular to a gate trench or trenches of the devices, a first isolation trench may be arranged on a first lateral side of the current sense transistor device, and a second isolation trench may be arranged on a laterally opposite second side of the current sense transistor device. In other words, the current sense transistor device may be embedded into a cell field of the vertical transistor device, e.g. with an isolation trench on each side between the current sense transistor device and the cell field. Referring to the removal of current lines as discussed above, the deep trench isolation may cut away current lines spreading laterally, e.g. the laterally outer or outermost current lines, see FIG. 5 for illustration.

In an embodiment, the current sense transistor is laterally embedded by the deep trench isolation and vertically embedded by the insulating element. In other words, the deep trench isolation together with the insulating element, i.e. backside isolation, forms an isolation well. As viewed in a vertical cross-section, the sectional plane lying for instance perpendicular to a gate trench or trenches of the devices, a first isolation trench may be arranged on one side of the current sense transistor device and a second isolation trench may be arranged on the laterally opposite side of the current sense transistor device, wherein the insulating element extends the entire way between the isolation trenches.

In an alternative embodiment, though being laterally embedded in the deep trench isolation, the drain region of the current sense transistor device may be contacted by a backside metallization at the second side of the semiconductor body in the area of the current sense transistor device. Laterally outside of the area of the current sense transistor device, the same backside metallization may make an electrical contact to the drain region of the vertical transistor device. In other words, the drain regions of the vertical and current sense transistor device may be connected via the backside metallization, wherein the deep trench isolation adds the additional resistance.

In this embodiment, an insulating element may extend below the deep trench isolation but have an opening below the current sense transistor device. As viewed in a vertical cross-section, a lateral width of this opening may be smaller than a lateral distance between the deep trenches enclosing the current sense transistor device. This lateral width of the opening may be used for adapting the additional resistance. Alternatively or in addition, the opening and, vice versa, a contact area formed in the opening, may be structured, e.g. into a plurality of sub-openings (with a regular or irregular pattern).

In an embodiment, the sense source region is arranged at the first side of the semiconductor body and the sense drain region is arranged at the second side of the semiconductor body. In other words, the current sense transistor device may be a vertical device. It may additionally comprise a sense gate trench, which extends from the first side into the semiconductor body. A sense body region may be arranged aside the sense gate trench, a sense gate electrode disposed in the sense gate trench and capacitively coupling to a channel region formed in the body region. Below the sense body region, the current sense transistor device may comprise a sense drift region. It may further comprise a sense field electrode, which capacitively couples to the sense drift region, the sense field electrode being for instance disposed in the sense gate trench below the sense gate electrode.

The sense gate electrode may have an elongated shape, e.g. form a stripe pattern as viewed in a vertical top view. The sense field electrode may have a stripe shape as well, i.e. be a field plate disposed below the sense gate electrode or in a separate trench side. Alternatively, the sense field electrode may have a columnar or needle-shape, e.g. be arranged in a needle-shaped trench. Independently of these details, the current sense transistor device and the vertical transistor device may have the same cell design, e.g. be manufactured in simultaneous process steps. Providing the devices with basically the same design may allow for an improved matching of the devices.

In an embodiment, the semiconductor die comprises a first vertical contact element, which is arranged in an area of the current sense transistor device and extends from the first side into the semiconductor body. The first vertical contact element may make an electrical contact to the sense drain region and connect it to the first side of the semiconductor body. In other words, the current may be routed along an additional vertical current path through the semiconductor body, which forms at least a portion of the additional resistance. The first vertical contact element may be combined with the isolation well discussed above, e.g. be arranged laterally inside of the isolation well.

In addition to the source and drain region arranged at opposite sides of the semiconductor body, the vertical transistor device may comprise a body region below the source region. From the first side, a gate trench may extend into the semiconductor body, a gate electrode being disposed in the gate trench and capacitively coupling to a channel region formed in the body region. Below the body region, a drift region may be arranged, the vertical device comprising for instance a field electrode capacitively coupling to the drift region. As discussed for the current sense transistor device above, the field electrode may have an elongated or needle/columnar shape. In the exemplary embodiments, an elongated field plate is disposed in the gate trench below the elongated gate electrode.

In an embodiment, at least a portion of the additional resistance is integrated into the drift region of the vertical transistor device. This may, for instance, be an additional current path extending through the drift region to the drain region of the vertical device. In other words, the drain region of the current sense transistor device may be electrically connected to the drain region of the vertical transistor device via the drift region of the vertical transistor device.

In an embodiment, the semiconductor die comprises a second vertical contact element, which is arranged in the area of the vertical transistor device and extends from the first side into the semiconductor body. The first and second vertical contact element may be electrically connected to each other at the first side of the semiconductor body, e.g. via a frontside metallization. Via the vertical contact elements, the drain regions of the transistor devices may be electrically connected to each other, the first vertical contact element making an electrical contact to the drain region of the current sense transistor device and the second vertical contact element making an electrical contact to the drain region of the vertical transistor device.

In an embodiment, a vertical contact element or the vertical contact elements comprise a sinker implant. The sinker implant may overrule a body implant which covers the whole frontside. By way of example, the sinker may have the same doping type like the drift region of the vertical transistor device, i.e. the same polarity. Therein, it may have a higher doping concentration than the drift region of the vertical transistor device, e.g. at least 10 times larger (with a possible upper limit of 1000 times). Independently of these details, the sinker implant may form a lower portion of the respective vertical contact element, e.g. in combination with a contact plug intersecting an insulating layer arranged on the first side of the semiconductor body and forming an upper portion of the vertical contact element.

In an embodiment, a vertical contact element or the vertical contact elements comprise a source doping. The body doping may be interrupted where the source doping is arranged. The source doping may be made of the same doping type as the source region of the vertical device and/or of the sense source region, e.g. of a first doping type. The source doping may form a portion of the respective vertical contact element, e.g. in combination with a contact plug intersecting an insulating layer arranged on the first side of the semiconductor body and forming another portion of the vertical contact element. The source doping may be shallower than the contact plug, so that the contact plug intersects the source doping vertically.

In an embodiment, the additional resistance has a first vertical portion aside the current sense transistor device, e.g. in the drift region aside. Further, it may comprise a second vertical portion aside the vertical transistor device, e.g. in the drift region aside. Further, it may comprise a horizontal portion, which may be arranged in the semiconductor substrate. The first vertical portion may run through an epitaxial layer which comprises the drift region of the current sense transistor device, and the second vertical portion may run through an epitaxial layer which comprises the drift region of the vertical transistor device and, additionally, may run through the substrate of the vertical transistor device. The drift regions of the devices may be formed in the same epitaxial layer. Laterally between the first and second vertical portion, a deep trench isolation may be arranged, see in detail above.

In an embodiment, the semiconductor die comprises a backside metallization, which is arranged on the second side of the semiconductor body. The backside metallization may be structured, i.e. have an interruption in an area of the current sense transistor device. Therein, a lateral edge of the backside metallization, which defines the interruption laterally, may be arranged with a lateral offset to the current sense transistor device, e.g. to a deep trench isolation in which the current sense transistor device is embedded laterally.

The lateral offset between the lateral edge of the backside metallization and the deep trench isolation may result in the second vertical portion of the additional resistance having a diagonal component in the semiconductor body. In other words, a lateral component is added to the vertical component, which may (further) extend the current path. Increasing the lateral offset may increase the lateral component, whereas decreasing the lateral offset may decrease the lateral component, which may allow for a respective adaption of the additional resistance.

In an embodiment, a method of designing a semiconductor die comprises arranging the transistor devices and adding the additional resistance on the drain side of the current sense transistor device. As discussed in detail above, the additional resistance may compensate for a current spreading in the current sense transistor device, e.g. to adjust a desired proportionality factor.

In an embodiment, a method of manufacturing the semiconductor die comprises forming the vertical transistor device, forming the current sense transistor device, and forming the additional resistance. As detailed above, the process steps may, at least to some extent, be performed simultaneously. For example, the vertical and the current sense transistor device may be formed simultaneously. Upfront, i.e. prior to the manufacturing of semiconductor die, the additional resistance may be chosen or adapted as described above.

### BRIEF DESCRIPTION OF THE DRAWINGS

Below the semiconductor die with the vertical transistor device and the current sense transistor device is explained in further detail by means of exemplary embodiments. Therein, the individual features can also be relevant in different combinations.

FIG. 1 shows a vertical transistor device and a current sense transistor device connected as a current mirror;

FIG. 2 shows a cross-section through a semiconductor die comprising a vertical transistor device and a current sense transistor device;

FIG. 3 shows a schematic vertical top view of the semiconductor die of FIG. 2;

FIG. 4 illustrates another semiconductor die with a vertical transistor device and a current sense transistor device in a vertical cross-section;

FIG. 5 shows another semiconductor die with a vertical transistor device and a current sense transistor device in a vertical cross-section;

FIG. 6 shows a schematic vertical top view of the semiconductor die of FIG. 5;

FIG. 7 shows another semiconductor die with a vertical transistor device and a current sense transistor device in a vertical cross-section;

FIG. 8 shows a schematic vertical top view of the semiconductor die of FIG. 7;

FIG. 9 shows another semiconductor die with a vertical transistor device and a current sense transistor device in a vertical cross-section;

FIG. 10 shows another semiconductor die with a vertical transistor device and a current sense transistor device in a vertical cross-section;

FIG. 11 shows another semiconductor die with a vertical transistor device and a current sense transistor device in a vertical cross-section;

FIG. 12 summarizes some design and manufacturing steps.

### DETAILED DESCRIPTION

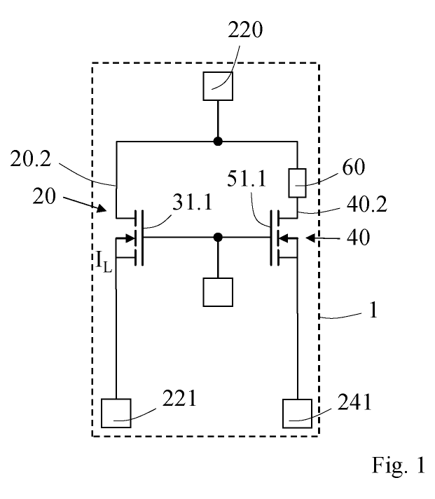

FIG. 1 shows a circuit diagram with a vertical transistor device 20 and a current sense transistor device 40, which are connected as a current mirror. A gate connection 31.1 of the vertical transistor device 20 is connected to a sense gate connection 51.1 of the current sense transistor device 40, e.g. to the same gate pad 231. Further, the vertical and the current sense transistor devices 20, 40 are, with their respective drain side 20.2, 40.2, connected to a common drain contact 220. When a current I_{L} flows through the vertical transistor device 20, i.e. between a source pad 221 and the drain pad 220, a respective sense current I_{S} is copied to the current sense transistor device 40. The sense current I_{S} can be sensed at a sense source pad 241 (which is a source contact of current sense transistor device 40).

Therein, the current ratio I_{L}/I_{S}, which is also referred to as a k_{ILIS} factor, is basically given by a size ratio of the vertical transistor device 20 and the current sense transistor device 40. However, the proportionality factor may vary, e.g. due a current spreading in the current sense transistor device 40. To compensate for this, an additional resistance 60 is arranged on the drain side 40.2 of the current sense transistor device 40, i.e. between the drain side 40.2 and the drain contact 220. In the embodiment shown, all elements of the circuit are integrated in a semiconductor die 1.

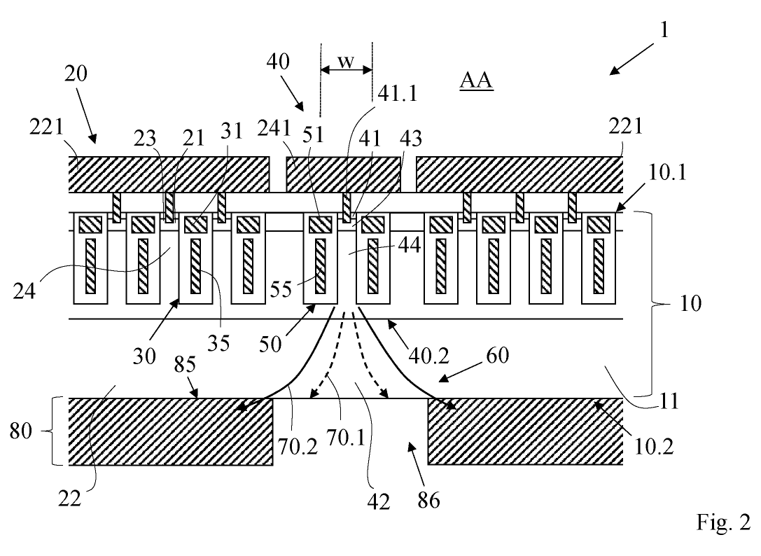

The vertical cross-section of FIG. 2 illustrates the vertical transistor device 20 and the current sense transistor device 40 integrated in the same semiconductor die 1. The vertical transistor device 20 comprises a source region 21 arranged at a first side 10.1 of a semiconductor body 10 and a drain region 22 arranged at a second side 10.2 of the semiconductor body 10. Below the source region 21, a body region 23 is arranged, laterally aside a gate trench 30. In the gate trench 30, a gate electrode 31 is disposed, which capacitively couples to the body region 23.

Vertically between the body region 23 and the drain region 22, a drift region 24 is arranged, which is made of the same doping type like the drain region 22, but with a lower doping concentration. The source region 21, drift region 24 and drain region 22 may be made of a first doping type, the body region 23 being made of a second doping type. In the example shown, the first type is n-type and the second type is p-type. In the gate trench 30, a field electrode 35 is disposed below the gate electrode 31, which capacitively couples to the drift region 24.

The current sense transistor device 40 comprises a sense source region 41 arranged at the first side 10.1 and a sense drain region 42 arranged at the second side 10.2 of the semiconductor body 10. Below the sense source region 41, a sense body region 43 is arranged, laterally aside a sense gate trench 50. In the sense gate trench 50, a sense gate electrode 51 is disposed, which capacitively couples to the sense body region 43. Vertically between the sense body region 43 and the sense drain region 42, a sense drift region 44 is arranged. In the example shown, the sense source region 41, sense drift region 44 and sense drain region 42 are made of a first doping type, the sense body region 43 being made of a second doping type, wherein the first type may be n-type and the second type p-type. In the sense gate trench 50, a sense field electrode 55 is disposed below the sense gate electrode 51, the sense field electrode 55 capacitively coupling to the sense drift region 44.

On the second side 10.2 of the semiconductor body 10, a backside metallization 80 is arranged. It has a contact area 85 towards the semiconductor body 10. In the embodiment shown, the contact area 85 has an interruption 86 below the current sense transistor device 40. With the interruption 86, the additional resistance 60 is added on the drain side 40.2 of the current sense transistor device 40. The drain side (40.2) may begin at a transition from a drift region (44) of the current sense transistor device (40) into the sense drain region (42); or at a transition from the body region (43) of the current sense transistor device (40) into the drift region (44) of the current sense device (40)

Considering a flow field with current flow lines 70.1, 70.2 in the semiconductor body 10, only the outer current flow lines 70.2 reach towards the backside metallization 80, whereas the inner current flow lines 70.1 are cut out by the interruption 86 (shown as dashed lines).

In the embodiment of FIG. 2, the interruption 86 extends over and beyond the entire lateral width w of the current sense transistor device 40. By adjusting the lateral extension of the interruption 86, the additional resistance 60 can be adapted, it can be increased by increasing the extension of the interruption 86.

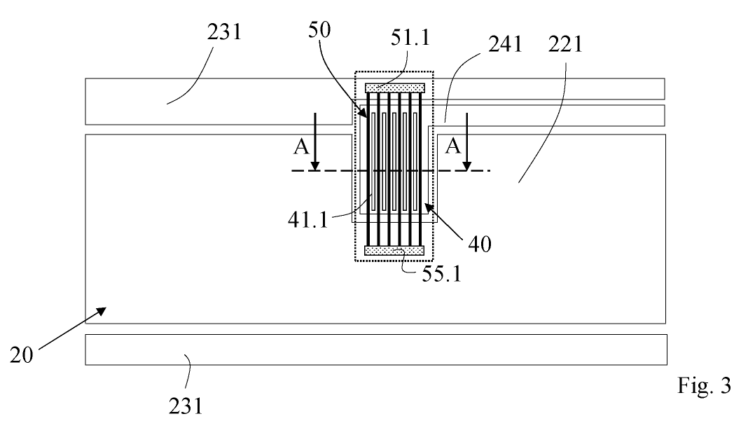

FIG. 3 illustrates a current sense transistor device 40 embedded into a vertical transistor device 20 in a schematic top view. For the current sense transistor device 40, the current sense trenches are illustrated as parallel stripes. Apart from the different number of trenches, this embodiment corresponds to cross-section of FIG. 2, see the sectional plane AA. At one lateral end of the sense gate trenches 50, the respective sense gate electrodes (not referenced here) are connected to the gate pad 231 via the sense gate connection 51.1 (which is vertical interconnect). At the opposite lateral end, the sense field electrodes are connected to the source pad 221 via a sense field electrode connection 55.1 (the vertical interconnect contacts the respective sense field electrode aside the sense gate electrode). Via a respective sense source connection 41.1, the sense source regions (referenced in FIG. 2) are respectively connected to the current sense pad 241 (the sense source connection 41.1 is also referenced in FIG. 2).

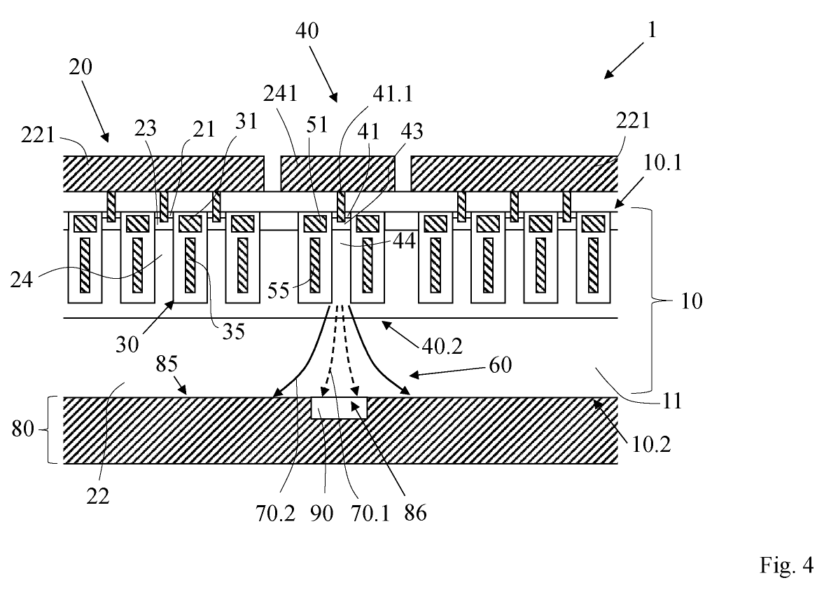

The vertical cross-section of FIG. 4 illustrates a vertical transistor device 20 and a current sense transistor device 40 integrated in the same semiconductor die 1. Basically, the design corresponds to the one discussed in detail with reference to FIG. 2. Generally, in this disclosure, the like reference numerals indicate the like elements or elements having the like function. Reference is made to the description of the respectively other figures as well, and the following description highlights mainly the differences.

Again, the additional resistance 60 is added by an interruption 86 of the contact area 85, which cuts out the inner current flow lines 70.1. In the embodiment of FIG. 4, the interruption 86 is realized by an insulating element 90 arranged on the second side 10.2 of the semiconductor body 10. The insulating element 90 is deposited and structured prior to a deposition of the backside metallization 80, it interrupts the contact area 85 locally. The backside metallization 80 as such may extend uninterrupted, i.e. as a non-structured continuous layer.

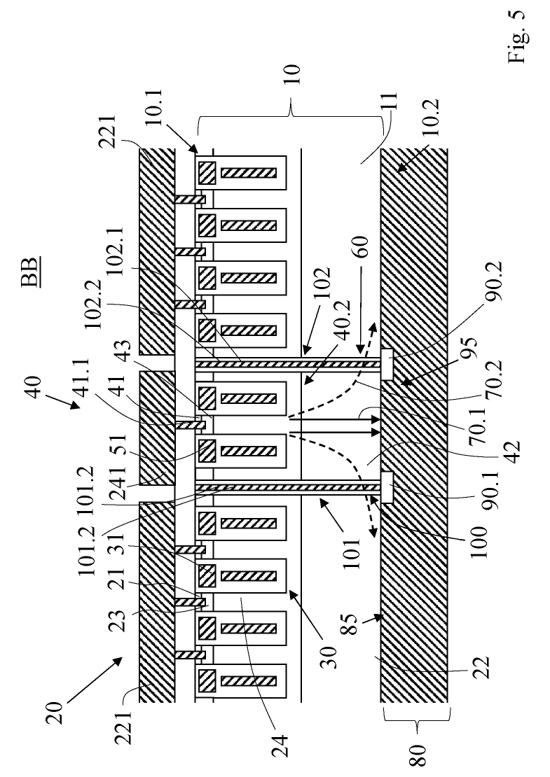

In the embodiment of FIG. 5, the outer current flow lines 70.2 are cut out, whereas the inner current flow lines 70.1 reach down to the backside metallization 80. This is achieved with a deep trench isolation 100, which comprises a first isolation trench 101 and a second isolation trench 102. The isolation trenches 101, 102 respectively reach from the first side 10.1 to the second side 10.2 of the semiconductor body 10. They are filled with a non-conductive liner 101.1, 102.1 and a conductive filler 101.2, 102.2, wherein an insulating element 90.1, 90.2 is arranged below each isolation trench 101, 102. Inside the semiconductor body 10, the vertical transistor device 20 and the current sense transistor device 40 are isolated from each other by the deep trench isolation 100, but the backside metallization 80 electrically connects the drain region 22 and the sense drain region 42.

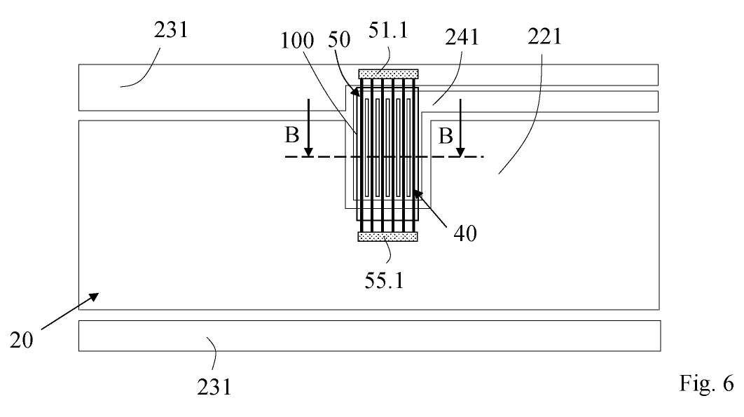

FIG. 6 shows an embodiment with a deep trench isolation 100 between the vertical transistor device 20 and the current sense transistor device 40 in a schematic vertical top view. Apart from the number of sense gate trenches 50, it corresponds to the sectional view of FIG. 5, see the sectional plane BB. The deep trench isolation 100 is arranged laterally between the vertical transistor device 20 and current sense transistor device 40. As viewed in a vertical top view, the deep trench isolation 100 may surround the current sense transistor device 40, i.e. enclose it to each side. As to further connection details of the current sense transistor device 40, reference is made to FIG. 3.

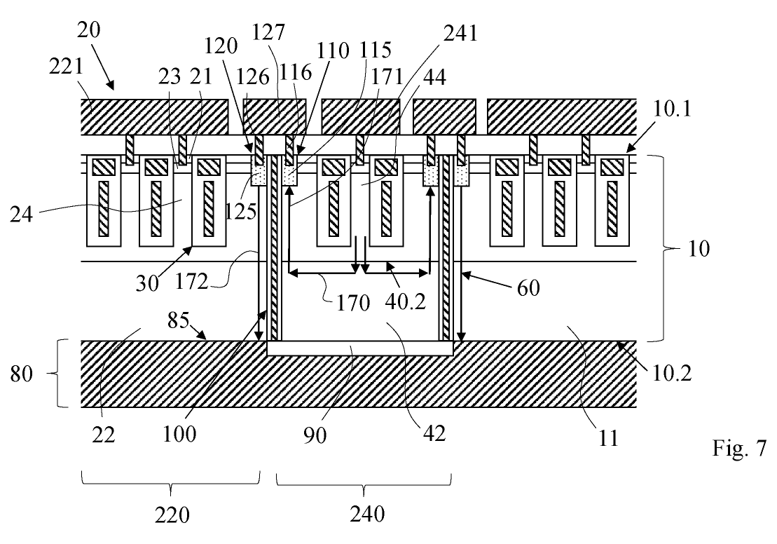

In the embodiment of FIG. 7, a deep trench isolation 100 is combined with an insulating element 90 arranged on the second side 10.2 of the semiconductor body 10. The current sense transistor device 40 is laterally and vertically embedded in this isolation well, the sense drain region 42 is not connected to the backside metallization 80 in the area of the current sense transistor device 40.

The current path is extended on the drain side 40.2 of the current sense transistor device 40. The additional resistance 60 has a first horizontal portion 170 in the sense drain region 42, i.e. in the semiconductor substrate 11. It further has a first vertical portion 171 aside the current sense transistor device 40, i.e. between the sense drain region 42 and a first vertical contact element 110. Further, it has a second vertical portion 172 aside the vertical transistor device 20, i.e. between a second vertical contact element 120 and the drain region 22 or backside metallization 80.

The first vertical contact element 110 is arranged inside the isolation well, namely in an area 240 of the current sense transistor device 40. The second vertical contact element 120 is arranged outside the isolation well, i.e. in an area 220 of the vertical transistor device 20. In the embodiment of FIG. 7, the vertical contact elements 110, 120 respectively comprise a sinker implant 115, 125. Via a respective contact plug 116, 126, they are connected to a connection pad 127, which electrically connects the first and second vertical portion 171, 172 of the additional resistance 60.

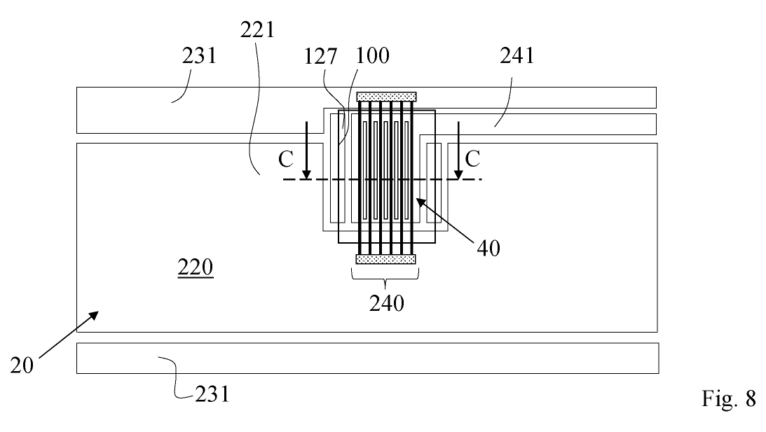

FIG. 8 illustrates such an embodiment in a schematic vertical top view, wherein the sectional plane CC of FIG. 7 is indicated. The connection pad 127 is arranged between the area 220 of the vertical transistor device and the area 240 of the current sense transistor device 40, wherein the deep trench isolation 100 extends below the connection pad 127. As to further connection details, reference is made to FIG. 3.

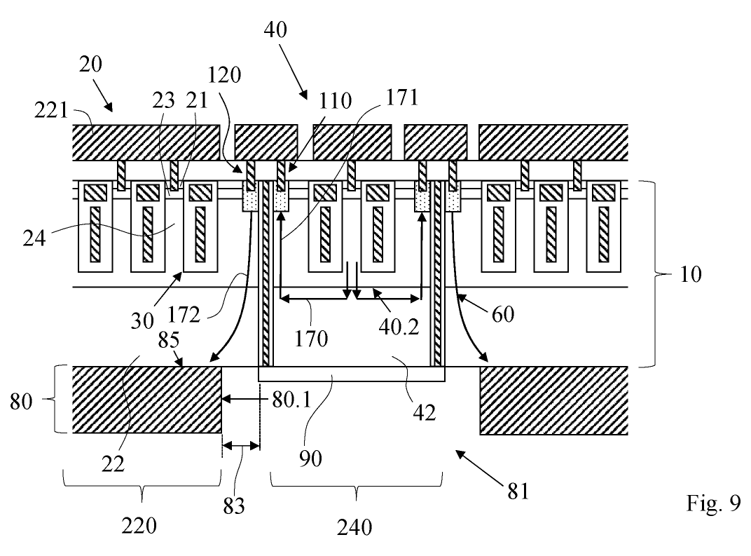

The embodiment of FIG. 9 basically corresponds to the one discussed with reference to FIG. 7 (and FIG. 8). It differs in that the backside metallization 80 is structured, namely provided with an interruption 81 in the area 240 of the current sense transistor device 40. Therein, a lateral edge 80.1 of the backside metallization 80 is arranged with a lateral offset 83 to the deep trench isolation 100. In consequence, the second vertical portion 172 of the additional resistance 60 has a diagonal component in the semiconductor body 10. In other words, it has a lateral component in addition to the vertical component, which extends the current path further.

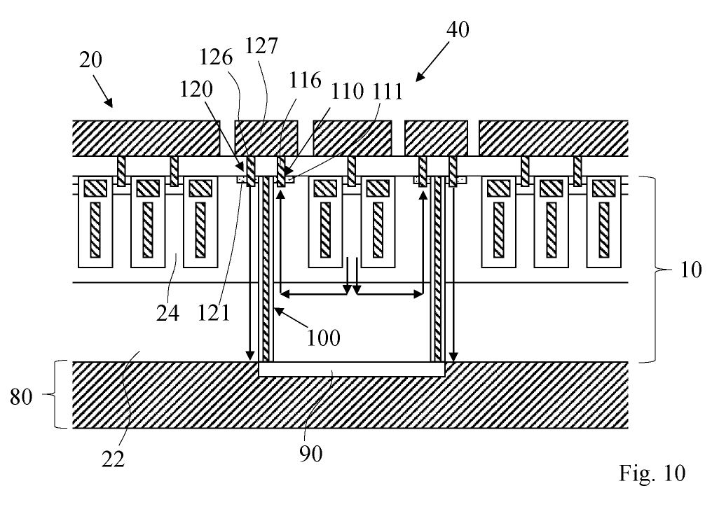

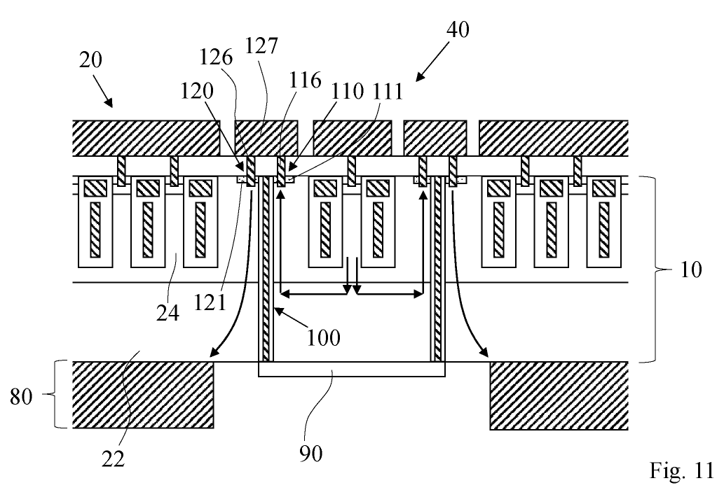

The embodiment of FIG. 10 basically corresponds to the one shown in FIG. 7, and the embodiment of FIG. 11 basically corresponds to the one shown in FIG. 9. They differ in the design of the vertical contact elements 110, 120. In FIGS. 10 and 11, the vertical contact elements 110, 120 respectively comprise a source doping 111, 121, into which the respective contact plug 116, 126 extends. The body doping is interrupted where a respective source doping 111, 121 is arranged.

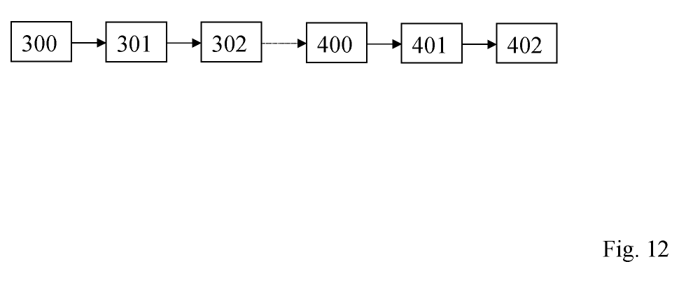

FIG. 12 summarizes some design and manufacturing steps in a flow diagram. A method of designing the semiconductor die may comprise arranging 300 the vertical transistor device, arranging 301 the current sense transistor device, and adding 302 the additional resistance on the drain side of the current sense transistor device. A subsequent method of manufacturing the semiconductor die may comprise forming 400 the vertical transistor device, forming 401 the current sense transistor device and forming 403 to the additional resistance. Though illustrated as a sequence, the respective process steps may happen simultaneously, e.g. in case of device cells having the same design and being monolithically integrated in the same die.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor die with a semiconductor body, the semiconductor die comprising:
a vertical transistor device comprising a source region at a first side of the semiconductor body and a drain region at a second side of the semiconductor body;
a current sense transistor device comprising a sense source region and a sense drain region in the semiconductor body;
an additional resistance integrated in the semiconductor die,
wherein the current sense transistor device is configured to sense an electrical current through the vertical transistor device, and
wherein the additional resistance is arranged on a drain side of the current sense transistor device.

2. The semiconductor die of claim 1, wherein at least a portion of the additional resistance is integrated in the semiconductor body below the drain side of the current sense transistor device.

3. The semiconductor die of claim 1, wherein at least a portion of the additional resistance is integrated in the semiconductor body in a sense drift region of the current sense transistor device.

4. The semiconductor die of claim 1, wherein at least a portion of the additional resistance is realized by a decreased conductivity in the semiconductor body due to a removal of current flow lines in the semiconductor body.

5. The semiconductor die of claim 1, wherein:
the drain side begins at a transition from a drift region of the current sense transistor device into the sense drain region; or
the drain side begins at a transition from the body region of the current sense transistor device into the drift region of the current sense device.

6. The semiconductor die of claim 1, further comprising:
a backside metallization arranged on the second side of the semiconductor body and having a contact area to the semiconductor body,
wherein the contact area has an interruption below the current sense transistor device.

7. The semiconductor die of claim 6, wherein the interruption, as viewed in a vertical cross-section, extends over at least 10% of a lateral width of the current sense transistor device.

8. The semiconductor die of claim 6, further comprising:
an insulating element arranged on the second side of the semiconductor body where the contact area has the interruption.

9. The semiconductor die of claim 8, wherein the backside metallization extends uninterrupted across the insulating element, and wherein the contact area is interrupted by the insulating element.

10. The semiconductor die of claim 1, further comprising:
a deep trench isolation arranged laterally between the vertical transistor device and the current sense transistor device.

11. The semiconductor die of claim 10, further comprising:
a backside metallization arranged on the second side of the semiconductor body and having a contact area to the semiconductor body, the contact area having an interruption below the current sense transistor device; and
an insulating element arranged on the second side of the semiconductor body where the contact area has the interruption,
wherein, as viewed in a vertical cross-section, the current sense transistor device is laterally and vertically embedded by the deep trench isolation and the insulating element.

12. The semiconductor die of claim 10, further comprising:
a backside metallization arranged on the second side of the semiconductor body and having a contact area to the semiconductor body, the contact area having an interruption below the current sense transistor device; and
an insulating element arranged on the second side of the semiconductor body where the contact area has the interruption,
wherein the insulating element extends below the deep trench isolation and has an opening below the current sense transistor device.

13. The semiconductor die of claim 1, wherein the sense source region is arranged at the first side of the semiconductor body and the sense drain region is arranged at the second side of the semiconductor body, wherein the current sense transistor device further comprises:
a sense gate trench extending from the first side into the semiconductor body; and
a sense body region aside the sense gate trench.

14. The semiconductor die of claim 13, further comprising:
a deep trench isolation arranged laterally between the vertical transistor device and the current sense transistor device;
a backside metallization arranged on the second side of the semiconductor body and having a contact area to the semiconductor body, the contact area having an interruption below the current sense transistor device;
an insulating element arranged on the second side of the semiconductor body where the contact area has the interruption, wherein, as viewed in a vertical cross-section, the current sense transistor device is laterally and vertically embedded by the deep trench isolation and the insulating element; and
a first vertical contact element extending in an area of the current sense transistor device from the first side into the semiconductor body, wherein the first vertical contact element makes electrical contact to the sense drain region and connects the sense drain region to the first side of the semiconductor body.

15. The semiconductor die of claim 14, wherein the first vertical contact element comprises a sinker implant.

16. The semiconductor die of claim 14, wherein the first vertical contact element comprises a source doping.

17. The semiconductor die of claim 1, wherein at least a portion of the additional resistance is integrated into a drift region of the vertical transistor device.

18. The semiconductor die of claim 17, further comprising:
a deep trench isolation arranged laterally between the vertical transistor device and the current sense transistor device;
a backside metallization arranged on the second side of the semiconductor body and having a contact area to the semiconductor body, the contact area having an interruption below the current sense transistor device;
an insulating element arranged on the second side of the semiconductor body where the contact area has the interruption, wherein, as viewed in a vertical cross-section, the current sense transistor device is laterally and vertically embedded by the deep trench isolation and the insulating element;
a first vertical contact element extending in an area of the current sense transistor device from the first side into the semiconductor body, wherein the first vertical contact element makes electrical contact to the sense drain region and connects the sense drain region to the first side of the semiconductor body;
a second vertical contact element extending in an area of the vertical transistor device from the first side into the semiconductor body,
wherein the first vertical contact element and the second vertical contact element are electrically connected to each other, and
wherein the second vertical contact element makes electrical contact to the drain region of the vertical transistor device and electrically connects the drain region of the vertical transistor device to the sense drain region.

19. The semiconductor die of claim 18, wherein at least one the first vertical contact element and the second vertical contact element comprises a sinker implant.

20. The semiconductor die of claim 18, wherein at least one the first vertical contact element and the second vertical contact element comprises a source doping.

21. The semiconductor die of claim 1, wherein the additional resistance between the drain region of the vertical transistor device and the drain side of the current sense transistor device has:
a first horizontal portion in the semiconductor body;
a first vertical portion aside the current sense transistor device; and
a second vertical portion aside the vertical transistor device.

22. The semiconductor die of claim 21, further comprising:
a deep trench isolation arranged laterally between the vertical transistor device and the current sense transistor device; and
a backside metallization having an interruption in an area of the current sense transistor device,
wherein a lateral edge of the backside metallization, which defines the interruption, is arranged with a lateral offset to the deep trench isolation, the second vertical portion of the resistance having a diagonal component in the semiconductor body.

23. A method of designing the semiconductor die of claim 1, the method comprising:
arranging the vertical transistor device;
arranging the current sense transistor device; and
adding the additional resistance on the drain side of the current sense transistor device.

24. A method of manufacturing the semiconductor die of claim 1, the method comprising:
forming the vertical transistor device;
forming the current sense transistor device; and
forming the additional resistance.
